(19) United States
(12) Patent Application Publication
(10) Pub. No.: US 2019/0280684 A1
(43) Pub. Date: Sep. 12, 2019

(54) PULSE WIDTH MODULATOR APPARATUS WITH ENHANCED RESOLUTION

(71) Applicant: SAMSUNG ELECTRO-MECHANICS CO., LTD., Suwon-si (KR)

(72) Inventor: Jin Yong KANG, Suwon-si (KR)

(73) Assignee: SAMSUNG ELECTRO-MECHANICS CO., LTD., Suwon-si (KR)

(21) Appl. No.: 16/167,999

(22) Filed: Oct. 23, 2018

(30) Foreign Application Priority Data
Mar. 12, 2018 (KR) 10-2018-0028687

(51) Int. Cl. H03K 7/08; H03K 5/133

(52) U.S. Cl. CPC H03K 7/08; H03K 2005/00058; H03K 5/133

(57) ABSTRACT

A pulse width modulation (PWM) apparatus includes an enable pulse generating circuit configured to generate an enable pulse signal based on a control clock, a short pulse generating circuit configured to generate a short pulse signal based on the enable pulse signal, a delay chain circuit configured to generate first to n^{th} delay signals based on the short pulse signal, each of the first to n^{th} delay signals having different delay times, a trigger circuit configured to select any one of the short pulse signal and the first to n^{th} delay signals and generate a trigger signal, in response to an input selection signal, and a PWM signal generating circuit configured to generate a PWM signal based on the trigger signal.

### CROSS-REFERENCE TO RELATED APPLICATION(S)

This application claims the benefit under 35 USC 119(a) of Korean Patent Application No. 10-2018-0028687 filed on Mar. 12, 2018 in the Korean Intellectual Property Office, the entire disclosure of which is incorporated herein by reference for all purposes.

### BACKGROUND

### 1. Field

This application relates to a pulse width modulation (PWM) apparatus with enhanced resolution.

### 2. Description of Related Art

In general, pulse width modulation (PWM) has been widely used to control actuators such as motors. Recently, a PWM approach with a PWM period of 1 MHz or more, and a resolution of 8 bits or more, has been implemented. In a digital circuit, when a PWM period is 1 MHz and a resolution is 10 bits, generally, a PWM pulse should be controlled with a clock of 1 GHz. In terms of time, a pulse should be controlled in 1 ns and, thus, a resolution of 1 ns may be ensured. In a related art method, a clock frequency is high compared with the alternate approaches where a PWM period is controlled in kHz and, thus, current consumed in hardware may be sharply increased. To generate a clock of 1 GHz, a Delay-Locked Loop (DLL) or a Phase-Locked Loop (PLL) IP may be used and, thus, an area and current consumption are increased.

A PWM digital circuit that uses a PLL clock of 1 GHz may be applied to a next-generation Optical Image Stabilizer (OIS) Driver Integrated Circuit (IC), and, thus, current consumption is increased. Current consumption in a digital circuit is proportional to an operating frequency and, when a PWM controller is embodied with a clock of 1 GHz, an increase of several tens of volts in current consumption may occur, as compared with the example in which a circuit is embodied with a delay element and a control clock of several tens of MHz. For example, there may be a problem in that current consumption of a circuit using a clock of 1 GHz may have a 20-fold increase in current consumption when compared with a circuit using a clock of 50 MHz.

A typical PWM device may desire a resolution of 1 ns in a PWM controller to form a signal with a PWM pulse period of 1 MHz and a resolution (N) of 10 bits and, thus, a clock (clk) frequency may be 1 GHz. Since a 10-bit counter may be desired, a 10-bit counter that operates at 1 GHz and a comparator may be desired, but, to embody these in the form of a digital circuit, it is difficult to use a microminiature process or to use a quick cell with high current consumption.

One of the typical approaches for enhancing resolution has a problem in that a third period signal is generated using first and second periods to enhance resolution but a period is changed to generate a new period signal and to generate additional frequency noise. However, this typical approach has disadvantages.

### SUMMARY

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a pulse width modulation (PWM) apparatus includes an enable pulse generating circuit configured to generate an enable pulse signal based on a control clock, a short pulse generating circuit configured to generate a short pulse signal based on the enable pulse signal, a delay chain circuit configured to generate first to n^{th} delay signals based on the short pulse signal, each of the first to nth delay signals having different delay times, a trigger circuit configured to select any one of the short pulse signal and the first to n^{th} delay signals and generate a trigger signal, in response to an input selection signal, and a PWM signal generating circuit configured to generate a PWM signal based on the trigger signal.

The enable pulse generating circuit may include a counter configured to count the control clock for a predetermined period and provide a count value, a first comparator configured to generate a first pulse when the count value and a first time value are equal, a second comparator configured to generate a second pulse when the count value and a second time value are equal, a logical sum operator configured to logically sum the first pulse and the second pulse and generate the enable pulse signal.

The short pulse generating circuit may include a delay device configured to delay the enable pulse signal by a predetermined time and a logical product operator configured to perform a logical product on a negative signal of an output signal of the delay device and the enable pulse signal to generate the short pulse signal at a high level for the delayed time.

The delay chain circuit may include a first delay device to an n^{th} delay device connected with each other in series, wherein the first delay device is configured to receive the short pulse signal and provide a first delay signal delayed by a predetermined time, wherein the n^{th} delay device is configured to receive a (n−1)^{th} delay signal from a (n−1)^{th} delay device and provide an n^{th} delay signal delayed by a predetermined time, and wherein n is a natural number equal to or greater than 2.

The trigger circuit may include a multiplexer tree circuit configured to select any one of the short pulse signal and first to seventh delay signals and provide the trigger signal in response to the input selection signal when the input selection signal has 3 bits and the n^{th} delay signal is the seventh delay signal, a cycle-delay conversion circuit configured to count a number of rising edges of the short pulse signal and the first to seventh delay signals and provide a count output value for one period of the control clock, a timing control circuit configured to generate a first time delay and a second time delay, based on the count output value, and a multiplexer selection circuit configured to select one of the first time delay and the second time delay based on the short pulse signal.

The multiplexer tree circuit may include a first multiplexer configured to receive the short pulse signal and the first of the first to seventh delay signals, a first multiplexer configured to receive the short pulse signal and the first of the first to seventh delay signals, fifth and sixth multiplexers configured to receive two output signals of the first to fourth multiplexers, select one of the received output signals of the first to fourth multiplexers, and output the selected signal, in response to a second bit of the input selection signal, and a seventh multiplexer configured to receive output signals of the fifth and sixth multiplexers, select one of the received output signals of the fifth and sixth multiplexers, and provide the selected signal as the trigger signal, in response to a third bit of the input selection signal.

The cycle-delay conversion circuit may include eight registers for receiving the short pulse signal and the first delay signal to the seventh delay signal; and wherein each of the eight registers may include a first register configured to output eight cdc signals at a high level when each of the short pulse signal and the first to seventh delay signals is at a rising edge during one period of the control clock, a second register configured to maintain and output the eight cdc signals from the first register, a logic counter configured to count at least one signal at a high level among the eight cdc signals maintained and output by the second register and output a count value, and a third register configured to maintain the count value and provide a count output value.

The timing control circuit is configured to generate the first time delay and the second time delay according to the following Expressions: (1) T1=floor(t1/Tclk), T2=floor(t2/Tclk), (2) T1frac=(t1/Tclk)−T1, T2frac=(t2/Tclk)−T2, (3) TD1=floor(T1frac*cdc_out), TD2=floor (T2frac*cdc_out), where cdc_out is a count output value, Tclk is a period of the control clock, and t1 and t2 are predetermined first and second PWM output switch times.

The multiplexer selection circuit may include a logical sum operator configured to logically sum a first initial value and a second initial value, a selection register configured to receive an output signal of the logical sum operator through a clear terminal and provide an output signal that is changed in a falling edge of the short pulse signal, and a first multiplexer configured to select one of the first time delay and the second time delay to provide the selection signal sel in response to an output signal of the selection register, wherein the first initial value and the second initial value is any one of “0” and “1”.

In a general aspect, a pulse width modulation (PWM) apparatus includes, a pulse generating circuit configured to receive a control clock and generate a pulse signal, a first delay circuit configured to delay the pulse signal for a predetermined time and output a short pulse signal, a second delay circuit comprising a plurality of series-connected delay devices, each of the series-delay devices configured to delay the short pulse signal by respective predetermined times, and a signal generator configured to determine a resolution of a PWM signal based on an output of the second delay circuit.

Each of the respective predetermined times may be 1 ns.

The PWM apparatus may include a trigger circuit configured to select any one of the short pulse signal and the output of the second delay circuit and generate a trigger signal in response to an input selection signal.

In a general aspect, a method includes receiving, by a pulse generating circuit, a control clock, generating a pulse signal based on the received control clock, delaying, by a first delay circuit, the pulse signal for a time of 1 ns to output a short pulse signal, delaying, by a second delay circuit, the short pulse signal by predetermined delay times, and determining, by a signal generator, a resolution of a PWM signal based on an output of the second delay circuit.

The second delay circuit comprises a plurality of series-connected delay devices, each of the series-delay devices configured to delay the short pulse signal by the predetermined delay times.

Other features and aspects will be apparent from the following detailed description, the drawings, and the claims.

### BRIEF DESCRIPTION OF THE DRAWINGS

FIG. 1 is a block diagram showing an example of a pulse width modulation (PWM) apparatus;

FIG. 2 is a timing chart of an example of an enable pulse signal pulse_en output from the enable pulse generating circuit of FIG. 1;

FIG. 3 is a diagram showing an example of a short pulse generating circuit of FIG. 1;

FIG. 4 is a diagram showing an example of a delay chain circuit of FIG. 1;

FIG. 5 is a diagram showing an example of a multiplexer tree circuit of the trigger circuit of FIG. 1;

FIG. 6 is a timing chart for generation of a trigger signal of the trigger circuit of FIG. 1;

FIG. 7 is a diagram showing an example of a cycle-delay conversion circuit of FIG. 1;

FIG. 8 is a diagram showing an example of a waveform of a cdc signal of the cycle-delay conversion circuit of FIG. 7;

FIG. 9 is a diagram showing an example of a logic-1 counter of FIG. 13;

FIG. 10 is a diagram showing an example of a multiplexer selection circuit of the trigger circuit of FIG. 1;

FIG. 11 is a diagram showing an example of a waveform of a PWM signal in an Init0-initualization state;

FIG. 12 is a diagram showing an example of a waveform of a PWM signal in an Init1-initualization state;

FIG. 13 is a diagram showing an example of a PWM signal generating circuit of FIG. 1;

FIG. 14 is a diagram showing an example (T1=T2) of a trigger signal and a waveform of a PWM signal;

FIG. 15 is a diagram showing another example (T1≠T2) of a trigger signal and a waveform of a PWM signal; and

FIG. 16 illustrates a PWM signal according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

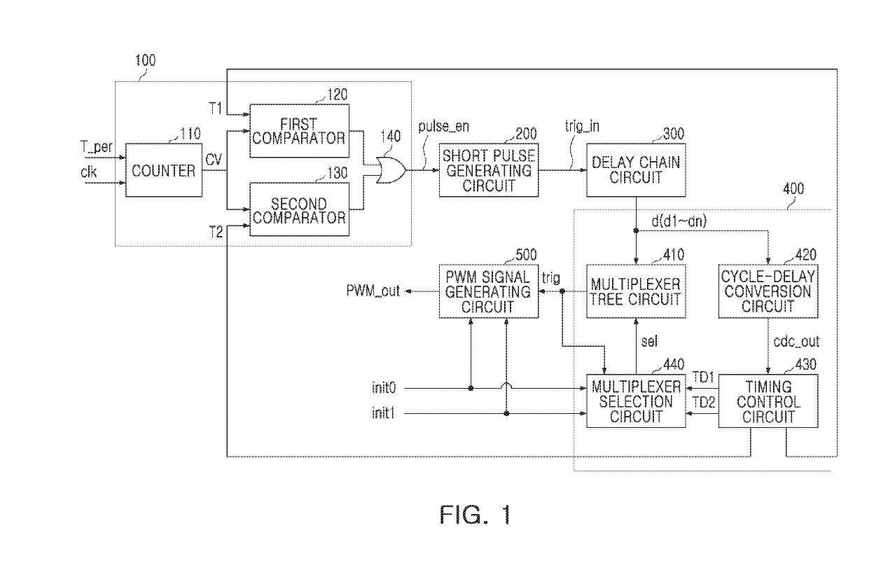

FIG. 1 is a block diagram showing an example of a pulse width modulation (PWM) apparatus.

Referring to FIG. 1, the PWM apparatus according to an example may include an enable pulse generating circuit 100, a short pulse generating circuit 200, a delay chain circuit 300, a trigger circuit 400, and a PWM signal generating circuit 500.

Herein, it is noted that use of the term “may” with respect to an example or embodiment, e.g., as to what an example or embodiment may include or implement, means that at least one example or embodiment exists where such a feature is included or implemented while all examples and embodiments are not limited thereto.

The enable pulse generating circuit 100 may generate an enable pulse signal pulse_en based on a control clock clk.

The short pulse generating circuit 200 may generate a short pulse signal trig_in based on the enable pulse signal pulse_en.

The delay chain circuit 300 may generate first to n^{th} delay signals d1 to dn with different delay time periods based on the short pulse signal trig_in.

The trigger circuit 400 may select any one of the short pulse signal trig_in and the first to n^{th} delay signals d1 to dn to generate a trigger signal trig in response to a received selection signal sel.

The PWM signal generating circuit 500 may generate a PWM signal based on the trigger signal trig.

With regard to the drawings of this application, a repeated description of components with the same reference numeral and the same function may be omitted and a difference in the drawings is described below.

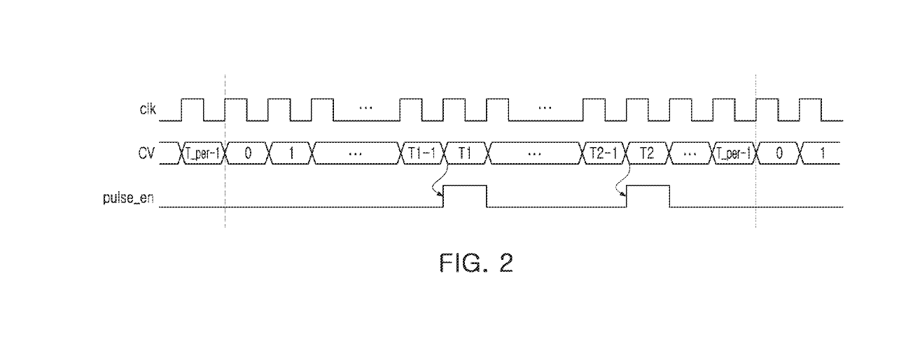

FIG. 2 is a timing chart of the enable pulse signal pulse_en that is output from the enable pulse generating circuit of FIG. 1.

Referring to FIGS. 1 and 2, the enable pulse generating circuit 100 may include a counter 110, a first comparator 120, a second comparator 130, and a logical sum operator 140.

The counter 110 may count the control clock clk for a predetermined period T_per to T_per and may provide a count value CV. For example, the counter 110 may begin to perform a count and may provide the count value CV upon receiving a first T_per and may begin to perform a new count upon receiving a next T_per. For example, the count value CV may be 0, 1, . . . T1-1, T1, . . . T2-1, T2, . . . .

The first comparator 120 may compare the count value CV and a first time value T1 and may generate a first pulse when the count value CV and the first time value T1 are the same or equal.

The second comparator 130 may compare the count value CV and a second time value T2 and may generate a second pulse when the count value CV and the second time value T2 are the same, or equal.

The logical sum operator 140 may logically sum the first pulse and the second pulse to generate the enable pulse signal pulse_en.

In detail, FIG. 2 shows a waveform that generates the enable pulse signal pulse_en to be input to the short pulse generating circuit 200 using the first pulse and the second pulse output from the first and second comparators 120 and 130. The counter 110 may perform a function of counting a PWM period and may generally change a PWM signal twice for each PWM period. FIG. 2 shows an example in which the enable pulse signal pulse_en is in a high-level state (e.g., 1) when the count value CV is T1 and T2.

For example, the first and second comparators 120 and 130 illustrated in FIG. 1 may be configured using one or two or more comparators.

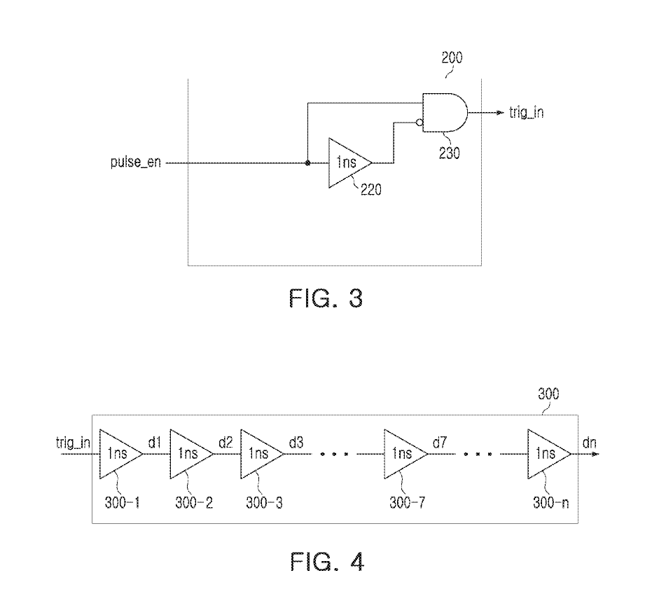

FIG. 3 is a diagram showing an example of the short pulse generating circuit of FIG. 1.

Referring to FIGS. 1 and 3, the short pulse generating circuit 200 may include a delay device 220 and a logical product operator 230.

The delay device 220 may delay the enable pulse signal pulse_en for a predetermined time (e.g., 1 ns) to maintain a high level of the short pulse signal trig_in.

The logical product operator 230 may perform a logical product on a negative signal of an output signal of the delay device 220 and the enable pulse signal pulse_en to generate the short pulse signal trig_in at a high level for the delayed time.

According to the aforementioned operation, the short pulse generating circuit 200 may receive the enable pulse signal pulse_en from the enable pulse generating circuit 100, may be synchronized with a rising edge of the enable pulse signal pulse_en to rise to a high level (logic “1”), and may generate the short pulse signal trig_in maintained at a high level (logic “1”) for approximately 1 ns. A width of the short pulse signal trig_in may be arbitrarily selected and, for example, a delay time of one delay element may be 1 ns.

FIG. 4 is a diagram showing an example of the delay chain circuit of FIG. 1.

Referring to FIGS. 1 and 4, the delay chain circuit 300 may include first to n^{th} delay devices 300-1 to 300-n connected to each other in series. This is merely an example, and, thus, the example is not limited thereto. As an example, the delay chain circuit 300 may be modified in various circuits as long as the same result is achieved.

The first delay device 300-1 may receive the short pulse signal trig_in and may provide a first delay signal dl that is delayed by a predetermined time.

The second delay device 300-2 may receive the first delay signal dl from the first delay device 300-1 and may provide a second delay signal d2 that is delayed by a predetermined time. The third delay device 300-3 may receive the second delay signal d2 from the second delay device 300-2 and may provide a third delay signal d3 that is delayed by a predetermined time.

The seventh delay device 300-7 may receive a sixth delay signal d6 from the sixth delay device 300-6 and may provide a seventh delay signal d7 that is delayed by a predetermined time. The n^{th} delay device 300-n (n being a natural number equal to or greater than 2) may receive a (n−1)^{th} delay signal d(n−1) from the (n−1)^{th} delay device 300-(n−1) and may provide an n^{th} delay signal dn that is delayed by a predetermined time.

Specifically, in the delay chain circuit 300 shown in FIG. 4, the resolution of a PWM signal may be determined based on the output of one delay device. For example, when 1 ns of resolution is embodied, one delay device may be configured with 1 ns. For example, when it is difficult to embody 1 ns of delay time in one combinational logic circuit, one delay device may be embodied by connecting a plurality of buffers or inverters in series with each other. In addition, the number of total delay devices may be determined in such a way that a total delay time in the delay chain circuit 300 is greater than a clock period. For example, when 20 MHz of clock is used, a period of one clock is 50 ns and, thus, the delay device may be embodied using 50 or more delay elements with 1 ns. In an example, a delay time may not be accurate and may be changed and, thus, the number of delay elements may be determined in consideration of an error range of this change. For example, according to an example, for explanation of an operation, the delay chain circuit 300 may include a total of eight delay devices with 1 ns and may provide eight delay signals.

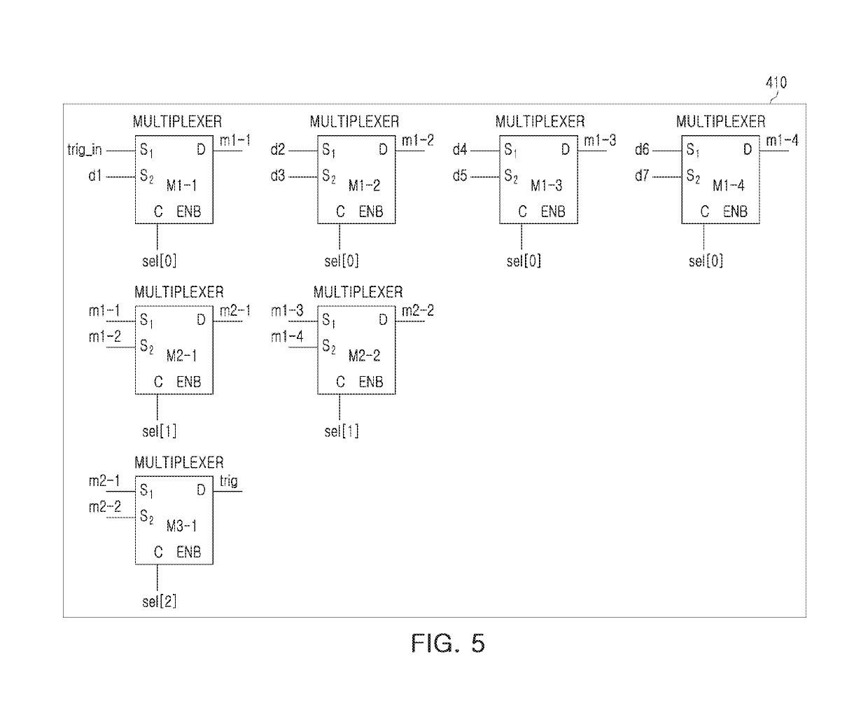

FIG. 5 is a diagram showing an example of a multiplexer tree circuit of the trigger circuit 400 of FIG. 1.

Referring to FIGS. 1 and 5, the trigger circuit 400 may include a multiplexer tree circuit 410, a cycle-delay conversion circuit 420, a timing control circuit 430, and a multiplexer selection circuit 440.

The multiplexer tree circuit 410 may select any one of the short pulse signal trig_in and the first to seventh delay signals d1 to d7 and may provide the selected signal as the trigger signal trig in response to the selection signal sel when the selection signal sel has 3 bits and the n^{th} delay signal dn is the seventh delay signal d7.

Referring to FIG. 5, the multiplexer tree circuit 410 may include first to fourth multiplexers M1-1 to M1-4, fifth and sixth multiplexers M2-1 and M2-2, and the seventh multiplexer M3-1 to select one delay signal from a plurality of delay signals output from the delay chain circuit 300. This is merely an example and is not limited thereto and the multiplexer tree circuit 410 may be modified in various circuits as long as the same result is achieved.

The first multiplexer M1-1 of the first to fourth multiplexers M1-1 to M1-4 may receive the short pulse signal trig_in and the first delay signal d1, and the second to fourth multiplexers M1-2 to M1-4 may receive two of the second to seventh delay signals d2 to d7 and may select and output one signal in response to a first bit of the selection signal sel.

The fifth and sixth multiplexers M2-1 and M2-2 may receive two output signals of the first to fourth multiplexers M1-1 to M1-4 and may select and output one signal in response to a second bit of the selection signal sel.

The seventh multiplexer M3-1 may receive an output signal of the fifth and sixth multiplexers M2-1 and M2-2 and may select and provide one of the output signals of the fifth and sixth multiplexers M2-1 and M2-2 to the trigger signal trig in response to a third bit of the selection signal sel.

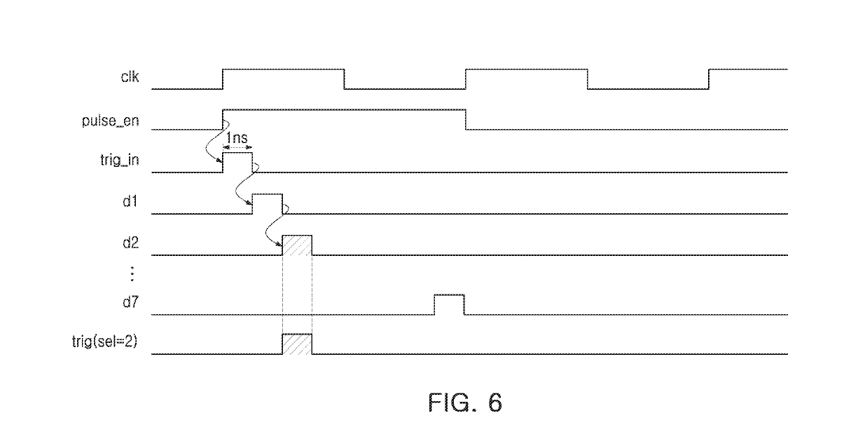

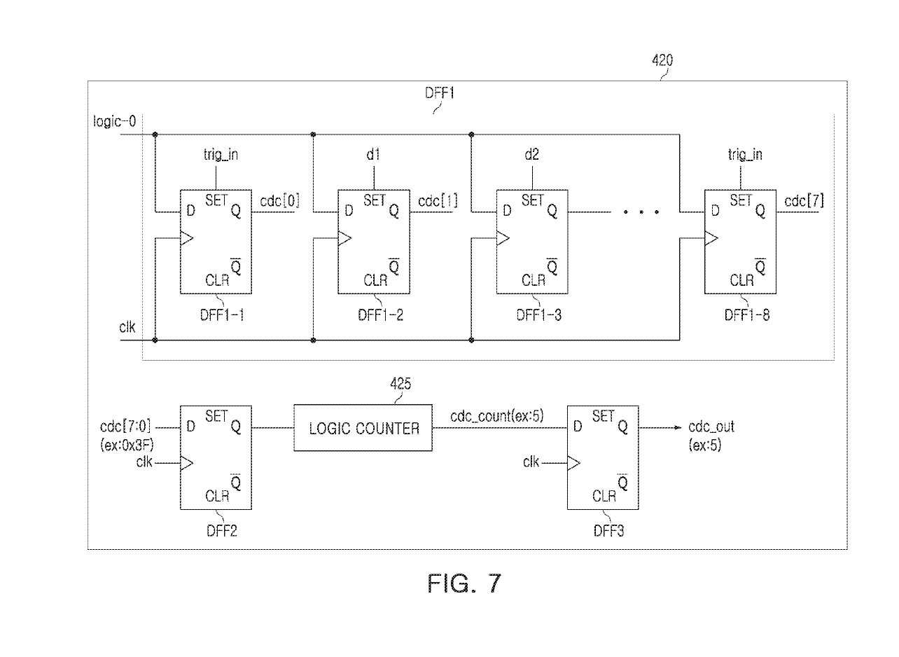

FIG. 6 is an example of a timing chart for generation of a trigger signal of the trigger circuit of FIG. 1.

Referring to FIGS. 5 and 6, the short pulse signal trig_in generated by the short pulse generating circuit 200 may be synchronized with a rising edge of the enable pulse signal pulse_en and may be input to each of the first to n^{th} delay devices 300-1 to 300-n to generate a delay signal that is delayed by 1 ns, and the multiplexer tree circuit 410 may select one of a plurality of delay signals and may output the selected delay signal to the trigger signal trig.

The trigger signal trig output from the multiplexer tree circuit 410 of FIG. 6 is illustrated on the assumption that the selection signal sel of the multiplexer selection circuit 440 is 2 (decimal number).

According to an example, the delay chain circuit 300 may determine the number of rising edges of delay signals (i.e., the number of delay devices) included during one cycle (one period) of a control clock and may control the PWM in a smaller time unit than a period of the control clock based on the result of the determination.

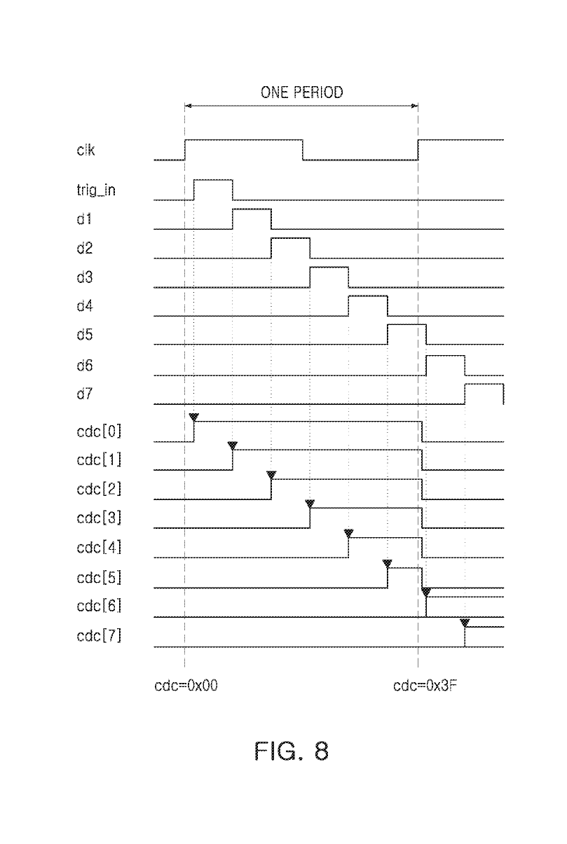

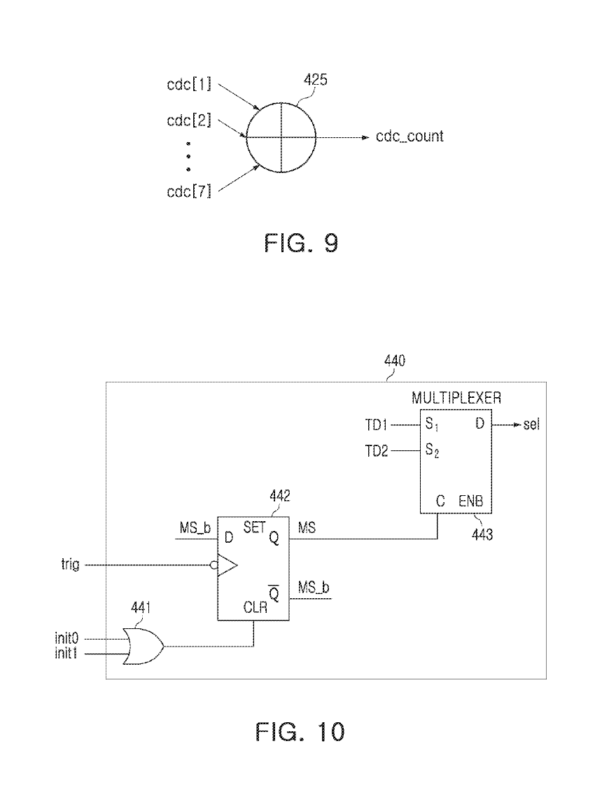

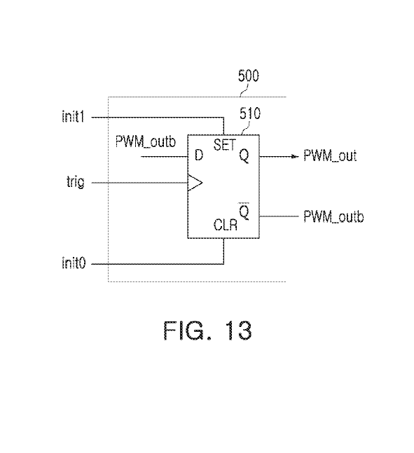

FIG. 7 is a diagram illustrating an example of the cycle-delay conversion circuit of FIG. 1. FIG. 8 is a diagram illustrating an example of a waveform of a cdc signal of the cycle-delay conversion circuit of FIG. 7. FIG. 9 is a diagram illustrating an example of a logic-1 counter of FIG. 13.

Referring to FIGS. 1, 7, 8, and 9, the cycle-delay conversion circuit 420 may count the number of rising edges of the short pulse signal trig_in and the first to seventh delay signals d1 to d7 during one period of the control clock clk and may provide a count output value cdc_out.

Referring to FIGS. 7 and 8, the cycle-delay conversion circuit 420 may include a first register DFF1, a second register DFF2, a logic counter 425, and a third register DFF3. This is merely an example and, thus, the present disclosure is not limited thereto and the cycle-delay conversion circuit 420 may be modified in various circuits as long as the same result is achieved.

The first register DFF1 may include eight registers DFF1-1 to DFF1-8 for receiving the short pulse signal trig_in and the first to seventh delay signals d1 to d7, and each of the eight registers DFF1-1 to DFF1-8 may output eight cdc signals cdc[0] to cdc[7] at a high level when each of the short pulse signal trig_in and the first to seventh delay signals d1 to d7 is at a rising edge during one period of the control clock clk.

In detail, in FIG. 7, the first to seventh delay signals d1 to d7 of the delay chain circuit 300 may be input to a SET terminal of each of the registers DFF1-1 to DFF1-8 in the first register DFF1 and logic-0 may be input to a data input D terminal of each of the registers DFF1-1 to DFF1-8. When the short pulse signal trig_in is input after a rising edge of the control clock clk, output Q of each of the registers DFF1-1 to DFF1-8 may be determined at a rising edge of a next control clock clk. For example, when output Q of each of the registers DFF1-1 to DFF1-8 is 0×3F, this means that one period of a control clock is similar to time delay caused in five delay devices and that the short pulse signal trig_in is being transmitted through a fifth delay device. Accordingly, delay time of one delay device may be determined to be 1.6 ns to 2.0 ns (10 ns/6 to 10 ns/5). In the following discussion, for convenience of description, delay time of one delay device is assumed to be 2.0 ns.

The second register DFF2 may maintain and output the eight cdc signals cdc[0] to cdc[7] from the first register DFF1.

The logic counter 425 may count a signal at a high level among the eight cdc signals cdc[0] to cdc[7] that are maintained and output by the second register DFF2 and may output the count output value cdc_count.

The third register DFF3 may maintain the count output value cdc_count and may provide the count output value cdc_out.

This is merely an example, and is not limited thereto. The logic counter 425 may be modified in various circuits as long as the same result is achieved.

Referring to FIG. 9, the logic counter 425 may count a signal (e.g., logic-1) at a high level among the eight cdc signals cdc[0] to cdc[7] input from the second register DFF2 and may output the count output value cdc_out.

For example, the logic counter 425 may be embodied as an adder and, when the eight cdc signals cdc[0] to cdc[7] input from the second register DFF2 are input to the adder, the number of signals at a high level (e.g., logic 1) among the eight cdc signals cdc[0] to cdc[7] input from the second register DFF2 may be output as the count output value cdc_cout of the adder.

For example, according to an example, when the adder is embodied, a first cdc[0] bit among cdc signals may be the same as the short pulse signal trig_n that is an input signal and an addition operation may be performed to exclude the first cdc[0] bit, so that the first cdc[0] bit is not included in a count value. In an example, if the count output value cdc_out is 5, this may mean that one period of an actual control clock is present between a time point of passing through a fifth delay device and a time point of passing through a sixth delay device and, thus, an addition operation may be performed to include the first cdc[0] bit among cdc signals.

According to this example, a circuit may be configured in such a way that each delay signal has a high level (e.g., logic 1) but may be configured in such a way that each delay signal has a low level (e.g., logic 0). The cycle-delay conversion circuit 420 may adjust an operation a number of times as necessary and, for example, may perform an operation for each PWM cycle. or may perform an operation at a predetermined time interval.

The timing control circuit 430 may generate first and second time delays TD1 and TD2 based on the count output value cdc_out.

The timing control circuit 430 may generate the first time delay TD1 and the second time delay TD2 according to Expressions 1, 2, and 3 below based on the count output value cdc_out, a period Tclk of the control clock clk, and predetermined first and second PWM output switch times t1 and t2.

T1=floor(t1/Tclk), T2=floor(t2/Tclk) Expression 1:

T1frac=(t1/Tclk)−T1, T2frac=(t2/Tclk)−T2 Expression 2:

TD1=floor(T1frac*cdc_out), TD2=floor(T2frac*cdc_out) Expression 3:

In Expressions 1 to 3 above, the predetermined first and second PWM output switch times t1 and t2, first time delay TD1, and second time delay TD2 may be generated by the timing control circuit 430, and refer to a time point at which a PWM device is controlled within a PWM period.

In Expressions 1 to 3 above, a floor function is a function that results in an integer and is a function for conversion into a maximum integer that does not exceed a range of an input value and results in discarding decimal places. Instead of the floor function, first decimal places may be rounded off.

In Expressions 1 to 3 above, t1 and t2 may refer to a switch time of changing a PWM signal and may have a range in 0 to a PWM period.

In Expressions 1 to 3 above, calculation may be performed assuming that the period Tclk of the control clock clk is 30 ns, the predetermined first PWM output switch time t1 is 250 ns, and the count output value cdc_out is 30.

That the count output value cdc_out is 30 may mean that one period of a control clock is the same as time delay of passing through 30 delay devices and that control may be performed with resolution obtained by dividing one period of the control clock into 30 pieces.

For example, according to Expression 1 above, T1 may be 8 according to floor (250/30) and, according to Expression 2 above, T1frac may be a value corresponding to a decimal point part of t1/Tclk.

Accordingly, according to Expression 3 above, the first time delay TD1 may be 10. Accordingly, when the predetermined second PWM output switch time t2 is 251 ns, T2 may be floor (251/30) and the second time delay TD2 may be 11.

As described above, according to an example, when a PWM device is used, resolution may be enhanced compared with a related art control method which uses only a control clock.

FIG. 10 is a diagram illustrating an example of a multiplexer selection circuit of the trigger circuit of FIG. 1.

Referring to FIGS. 1 and 10, the multiplexer selection circuit 440 may select one of the first and second time delays TD1 and TD2 to provide the selection signal sel based on the short pulse signal trig_in.

Referring to FIG. 10, the multiplexer selection circuit 440 may include a logical sum operator 441, a selection register 442, and a first multiplexer 443.

The logical sum operator 441 may logically sum first and second initial values init0 and init1.

The selection register 442 may receive an output signal of the logical sum operator 441 through a clear terminal and may provide an output signal that is changed in a falling edge of the short pulse signal trig_in.

The first multiplexer 443 may select one of the first time delay TD1 and the second time delay TD2 to provide the selection signal sel in response to an output signal of the selection register 442.

When the predetermined first time value T1 and first time delay TD1, and the predetermined second time value T2 and second time delay TD2 are included as a variable value, a pulse waveform may be changed twice within a period.

On the other hand, one of the first time delay TD1 and the second time delay TD2 may be fixed to a constant and may be used.

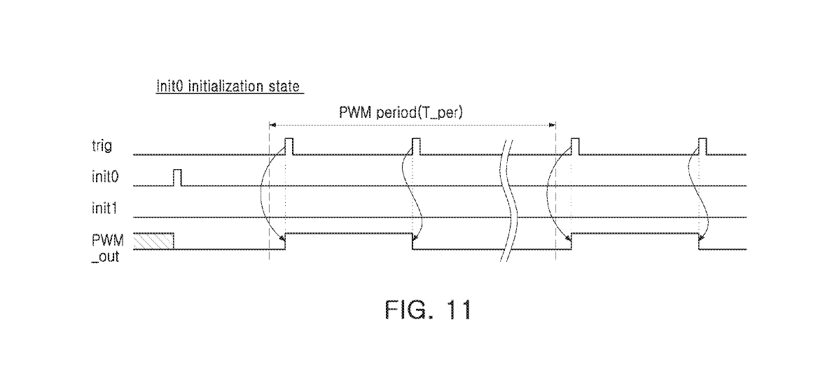

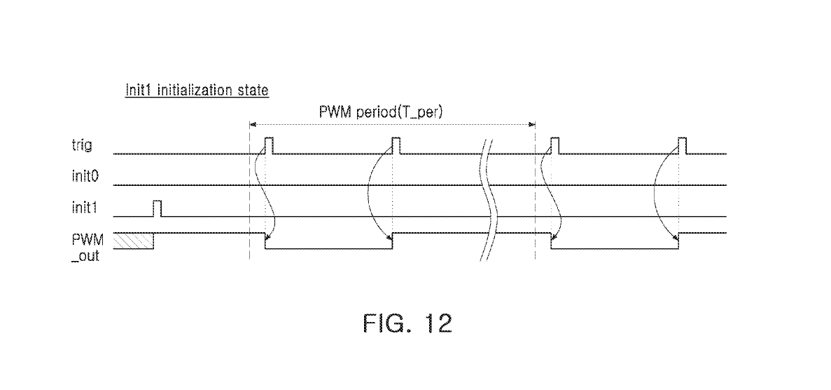

FIG. 11 is a diagram illustrating an example of a waveform of a PWM signal in an Init0-initiualization state. FIG. 12 is a diagram illustrating an example of a waveform of a PWM signal in an Init1-initiualization state.

FIGS. 11 and 12 illustrate waveforms of a PWM output signal in the init0-initiualization state and the init1-initiualization state, respectively and, as seen from FIGS. 11 and 12, waveforms of the PWM output signal may be reversed.

FIG. 13 is a diagram illustrating an example of the PWM signal generating circuit of FIG. 1.

Referring to FIG. 13, the PWM signal generating circuit 500 may include a register 510. The register 510 may receive a first initial value init0 through a clear CLR terminal, may receive a second initial value init1 through a set SET terminal, may receive the trigger signal trig through a clock terminal, and a data D terminal and a reversal output terminal Q̅ are connected and, accordingly, a PWM signal PWM_out or a reversed PWM signal PWM_outb may be generated through the output Q terminal based on the trigger signal trig.

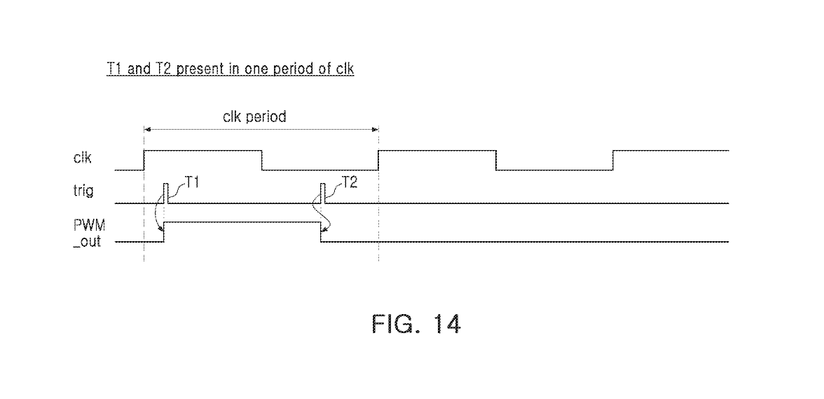

FIG. 14 is a diagram illustrating an example of a trigger signal and a waveform of a PWM signal and illustrates a waveform of a PWM signal when T1 and T2 are present in one period of the control clock clk, that is, when two trigger signals are present in one period of a control clock.

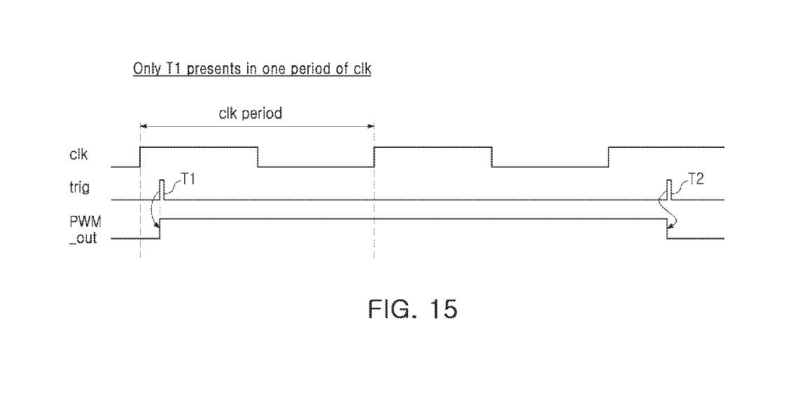

FIG. 15 is a diagram illustrating another example of a trigger signal and a waveform of a PWM signal and illustrates a waveform of a PWM signal when only one of T1 and T2 is present in one period of the control clock clk, that is, when only one trigger signal is present in one period of a control clock.

Referring to FIGS. 1, 13, 14, and 15, the PWM signal generating circuit 500 may receive the trigger signal trig through a clock terminal of the register 510. The register 510 may receive the reversed PWM signal PWM_outb through the data D terminal and, thus, a signal may be reversed and output whenever the trigger signal trig is generated.

To determine an initial value of the register 510, the first initial value init0 and the second initial value init1 may be received through the clear CLR terminal and the set terminal, respectively, and an initial state of a PWM signal may be set before PWM control begins.

For example, to set an initial state of PWM output to 0, 1 may be input to the first initial value init0 and, then, may be changed to 0 for a predetermined time period and, to set an initial state to 1, 1 may be input to the second initial value init1 and, then, may be changed to 0 for a predetermined time period.

Accordingly, when an initial state is 0, if a trigger signal trig is first input, a PWM output may be changed to 1, when a next trigger signal trig is input, a PWM output may be 0, and, a PWM signal may be repeated every period in this method.

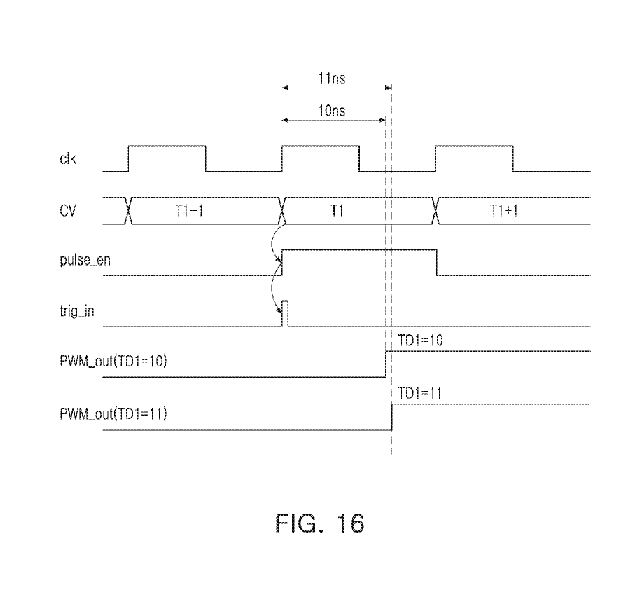

FIG. 16 illustrates a PWM signal according to an example.

FIG. 16 illustrates an example of a waveform of a PWM output PWM_out when TD1 is 10 and TD2 is 11. As seen from FIG. 16, even if a clock with a frequency of 30 ns is used as in the current example, a PWM pulse in 1 ns may be possible.

According to an example, a timing control circuit may be embodied in a computing environment in which a processor (e.g., a central processing unit (CPU), a graphic processing unit (GPU), a microprocessor, an application specific integrated circuit (ASIC), and a field programmable gate arrays(FPGA)), a memory (e.g., a volatile memory (e.g., RAM) and a non-volatile memory (e.g., ROM and a flash memory), an input device (e.g., a keyboard, a mouse, a pen, a voice input device, a touch input device, an infrared ray camera, and a video input device), an output device (e.g., a display, a speaker, and a printer) and a communication interface unit (e.g., MODEM, a network interface card (NIC), an integrated network interface, a wireless frequency transmitter/receiver, an infrared port, and a USB interface unit) are connected to each other (e.g., peripheral component interface (PCI), USB, firmware (IEEE 1394), optical bus configuration, and a network).

The computing environment may be embodied in a distributed computing environment or the like including a personal computer, a server computer, a handheld or laptop device, a mobile device (mobile phone, PDA, and media player), a multiprocessor system, a consumer electronic device, a minicomputer, a main frame computer, or the arbitrary aforementioned system or device but is not limited thereto.

An example may provide a PWM apparatus for generating a control clock with a relatively high frequency using a control clock with a relatively low frequency (e.g., several tens of MHz), thereby providing a PWM output with enhanced resolution.

As set forth above, according to the examples, to generate a PWM signal with a resolution of 1 ns, a control clock with a relatively high frequency may be generated using a control clock with a relatively low frequency (e.g., several tens of MHz) rather than using a relatively high clock such as a clock of 1 GHz, thereby providing a PWM output with enhanced resolution.

Specifically, a high frequency clock may not be used compared with a typical configuration for controlling a PWM waveform with a digital circuit and, thus, an effect of reduction in power consumption of a digital circuit, which is proportional to a clock frequency, may be achieved and a size and power consumption due to DLL or PLL for generating a high-frequency clock may be reduced. For example, a related art method uses a clock of 1 GHz to achieve a resolution of 1 ns. However, in the examples of this application, a high-frequency PWM may be achieved by implementing a plurality of delay elements and a control clock of several tens of MHz rather than using a clock of 1 GHz.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A pulse width modulation (PWM) apparatus comprising:
an enable pulse generating circuit configured to generate an enable pulse signal based on a control clock;
a short pulse generating circuit configured to generate a short pulse signal based on the enable pulse signal;
a delay chain circuit configured to generate first to n^{th} delay signals based on the short pulse signal, each of the first to n^{th} delay signals having different delay times;
a trigger circuit configured to select any one of the short pulse signal and the first to n^{th} delay signals and generate a trigger signal, in response to an input selection signal; and
a PWM signal generating circuit configured to generate a PWM signal based on the trigger signal.

2. The PWM apparatus of claim 1, wherein the enable pulse generating circuit comprises:
a counter configured to count the control clock for a predetermined period and provide a count value;
a first comparator configured to generate a first pulse when the count value and a first time value are equal;
a second comparator configured to generate a second pulse when the count value and a second time value are equal; and
a logical sum operator configured to logically sum the first pulse and the second pulse and generate the enable pulse signal.

3. The PWM apparatus of claim 1, wherein the short pulse generating circuit comprises:
a delay device configured to delay the enable pulse signal by a predetermined time; and
a logical product operator configured to perform a logical product on a negative signal of an output signal of the delay device and the enable pulse signal to generate the short pulse signal at a high level for the delayed time.

4. The PWM apparatus of claim 1, wherein the delay chain circuit comprises a first delay device to an n^{th} delay device connected with each other in series;
wherein the first delay device is configured to receive the short pulse signal and provide a first delay signal delayed by a predetermined time;
wherein the n^{th} delay device is configured to receive a (n−1)^{th} delay signal from a (n−1)^{th} delay device and provide an n^{th} delay signal delayed by a predetermined time, and
wherein n is a natural number equal to or greater than 2.

5. The PWM apparatus of claim 1, wherein the trigger circuit comprises:
a multiplexer tree circuit configured to select any one of the short pulse signal and first to seventh delay signals and provide the trigger signal in response to the input selection signal when the input selection signal has 3 bits and the n^{th} delay signal is the seventh delay signal;
a cycle-delay conversion circuit configured to count a number of rising edges of the short pulse signal and the first to seventh delay signals and provide a count output value for one period of the control clock;
a timing control circuit configured to generate a first time delay and a second time delay, based on the count output value; and
a multiplexer selection circuit configured to select one of the first time delay and the second time delay based on the short pulse signal.

6. The PWM apparatus of claim 5, wherein the multiplexer tree circuit comprises:
a first multiplexer configured to receive the short pulse signal and the first of the first to seventh delay signals;
second to fourth multiplexers configured to receive two of the first to seventh delay signals, select one of the received first to seventh delay signals, and output the selected signal, in response to a first bit of the input selection signal;
fifth and sixth multiplexers configured to receive two output signals of the first to fourth multiplexers, select one of the received output signals of the first to fourth multiplexers, and output the selected signal, in response to a second bit of the input selection signal; and
a seventh multiplexer configured to receive output signals of the fifth and sixth multiplexers, select one of the received output signals of the fifth and sixth multiplexers, and provide the selected signal as the trigger signal, in response to a third bit of the input selection signal.

7. The PWM apparatus of claim 5, wherein the cycle-delay conversion circuit comprises eight registers for receiving the short pulse signal and the first delay signal to the seventh delay signal; and
wherein each of the eight registers comprises:
a first register configured to output eight cdc signals at a high level when each of the short pulse signal and the first to seventh delay signals is at a rising edge during one period of the control clock;
a second register configured to maintain and output the eight cdc signals from the first register;
a logic counter configured to count at least one signal at a high level among the eight cdc signals maintained and output by the second register and output a count value; and
a third register configured to maintain the count value and provide a count output value.

8. The PWM apparatus of claim 5, wherein the timing control circuit is configured to generate the first time delay and the second time delay according to the following Expressions:
T1=floor(t1/Tclk), T2=floor(t2/Tclk) (1)
T1frac=(t1/Tclk)−T1, T2frac=(t2/Tclk)=T2, (2)
TD1=floor(T1frac*cdc_out), TD2=floor(T2frac*cdc_out) (3)
where cdc_out is a count output value, Tclk is a period of the control clock, and t1 and t2 are predetermined first and second PWM output switch times.

9. The PWM apparatus of claim 5, wherein the multiplexer selection circuit comprises:
a logical sum operator configured to logically sum a first initial value and a second initial value;
a selection register configured to receive an output signal of the logical sum operator through a clear terminal and provide an output signal that is changed in a falling edge of the short pulse signal; and
a first multiplexer configured to select one of the first time delay and the second time delay to provide the selection signal sel in response to an output signal of the selection register,
wherein the first initial value and the second initial value is any one of “0” and “1”.

10. A pulse width modulation (PWM) apparatus comprising:
a pulse generating circuit configured to receive a control clock and generate a pulse signal;
a first delay circuit configured to delay the pulse signal for a predetermined time and output a short pulse signal;
a second delay circuit comprising a plurality of series-connected delay devices, each of the series-delay devices configured to delay the short pulse signal by respective predetermined times; and
a signal generator configured to determine a resolution of a PWM signal based on an output of the second delay circuit.

11. The PWM apparatus of claim 10, wherein each of the respective predetermined times are 1 ns.

12. The PWM apparatus of claim 10, further comprising a trigger circuit configured to select any one of the short pulse signal and the output of the second delay circuit and generate a trigger signal in response to an input selection signal.

13. A method comprising:
receiving, by a pulse generating circuit, a control clock;
generating a pulse signal based on the received control clock;
delaying, by a first delay circuit, the pulse signal for a time of 1 ns to output a short pulse signal;
delaying, by a second delay circuit, the short pulse signal by predetermined delay times; and
determining, by a signal generator, a resolution of a PWM signal based on an output of the second delay circuit.

14. The method of claim 13, wherein the second delay circuit comprises a plurality of series-connected delay devices, each of the series-delay devices configured to delay the short pulse signal by the predetermined delay times.
